(19) United States
(12) Patent Application Publication
(10) Pub. No.: US 2015/0351270 A1
(43) Pub. Date: Dec. 3, 2015

(54) ELECTRIC WIRE PRESSURE-CONTACT STRUCTURE

(71) Applicant: Yazaki Corporation, Tokyo (JP)

(72) Inventor: Tetsuro TAKASAKI, Makinohara-shi (JP)

(73) Assignee: Yazaki Corporation, Tokyo (JP)

(21) Appl. No.: 14/825,666

(22) Filed: Aug. 13, 2015

Related U.S. Application Data
(63) Continuation of application No. PCT/JP2014/053049, filed on Feb. 10, 2014.

(30) Foreign Application Priority Data
Feb. 14, 2013 (JP) 2013-026725

(51) Int. Cl. H05K 5/02; H02G 5/08

(52) U.S. Cl. CPC H05K 5/0247; H02G 5/08; H05K 5/0221

(57) ABSTRACT

An electric wire pressure-contact structure includes an electric wire holder which retains electric wires, and a housing in which bus bars having pressure-contact blades are housed. Lock sections include locked parts provided to the electric wire holder, and the locking parts provided to the housing. In each retaining groove, the electric wire holder includes: protrusions which bring the electric wire into pressure contact with the pressure-contact blade by pressing the electric wire; and a recess which forms a bent section in the electric wire when the electric wire is pressed by the protrusions. A length between apexes of the protrusions and a bottom of the recess is set to be longer than a gap between the locked part and the locking part in each lock section. The gap is formed when the locked parts are loosely fitted in the locking parts.

### CROSS REFERENCE TO RELATED APPLICATION

This is a continuation application based on PCT application No. PCT/JP2014/053049 filed on Feb. 10, 2014, which claims the benefit of priority from Japanese Patent Application No. 2013-026725 filed on Feb. 14, 2013, the entire contents of which are incorporated by reference herein.

### BACKGROUND OF THE INVENTION

1. Field of the Invention

The present invention relates to an electric wire pressure-contact structure.

2. Description of the Related Art

There has been known an electric wire pressure-contact structure including: an electric wire holder configured to retain electric wires; and a cover (housing) in which terminals (bus bars) having contact-pressure blades are housed with the electric wires put in pressure contact with the contact-pressure blades. When the electric wire holder is inserted and fitted into the cover, the electric wires are brought into pressure contact with the contact-pressure blades, and the two end sides of each electric wire are drawn out of the cover in a direction opposite to a direction of the insertion (see Patent Literature 1: Japanese Patent Application Publication No. 2012-109163, for example).

This electric wire pressure-contact structure includes a lock section formed from: a locked part provided to the electric wire holder; and a locking part provided to the cover. The loose fitting of the locked part of the electric wire holder in the locking part of the cover makes the cover hold the electric holder. The electric wire holder is provided with: retaining grooves configured to retain the respective electric wires; and pressure-contact blade entry slits (insertion grooves) into which the contact-pressure blades are inserted.

When the cover is fitted to the electric wire holder, the pressure-contact blades of the terminals housed in the cover enter the pressure-contact blade entry slits, and the pressure-contact blades are connected to the conductors of the electric wires. In this process, the locked part of the electric wire holder is loosely fitted in the locking part of the cover. Even if tensile force is applied to the electric wire(s) in this state, the locked part of the electric wire holder is locked to a side surface of the locking part of the cover on a side where the electric wire holder is detachable from the cover. For this reason, the electric wire holder is not detached from the cover.

In the lock section formed from the locked part of the electric wire holder and the locking part of the cover in the electric wire pressure-contact structure of Patent Literature 1, when the locked part is loosely fitted in the locking part, a gap is formed between the locked part and the locking part on the side where the electric wire holder can be detached from the cover. For this reason, when the tensile force is applied to the electric wire, the electric wire holder moves by this gap in the detachment direction of the electric wire holder from the cover.

In the electric wire pressure-contact structure of Patent Literature 1, if the electric wire holder moves in the detachment direction of the electric wire holder from the cover, the electric wires retained by the electric wire holder also move in the detachment direction together with the electric wire holder. This displaces pressure-contact positions of the electric wires with respect to the pressure-contact blades, which may result in decrease in the reliability of the connection between the electric wires and the bus bars.

### SUMMARY OF THE INVENTION

An object of the present invention is to provide an electric wire pressure-contact structure which is capable of enhancing the reliability of the connection between the electric wires and the bus bars.

A first aspect of the present invention provides an electric wire pressure-contact structure characterized as follows. The electric wire pressure-contact structure includes: an electric wire holder configured to retain an electric wire; and a housing in which a bus bar is housed, the bus bar having a pressure-contact blade for pressure contacting the electric wire. When the electric wire holder is inserted and fitted into the housing, the electric wire is brought into pressure contact with the pressure-contact blade, and two end sides of the electric wire are drawn out of the housing in a direction opposite to a direction of the insertion. A locking part is provided to one of the electric wire holder and the housing, while a locked part is provided to the other of the electric wire holder and the housing. A lock section includes the locking part and the locked part. The lock section makes the housing hold the electric wire holder by loosely fitting the locked part into the locking part. The electric wire holder includes: a retaining groove configured to retain the electric wire; an insertion groove provided on a bottom side of the retaining groove, the pressure-contact blade being inserted in the insertion groove; a pair of protrusions provided projecting from an opening side of the insertion groove, and arranged opposite each other with respect to the pressure-contact blade while the pressure-contact blade is inserted in the insertion groove, and configured to bring part of the electric wire into pressure contact with the pressure-contact blade by pressing the electric wire; and a recess provided between the protrusions, and configured to form a bent section in the electric wire when pressed by the protrusions. A length between apexes of the protrusions and a bottom of the recess is set to be longer than a gap between the locked part and the locking part in the lock section, where the gap is formed when the locked part is loosely fitted in the locking part in the lock section, and is on a side where the electric wire holder is detachable from the housing.

In the electric wire pressure-contact structure according to this aspect, the electric wire holder includes: the pair of protrusions provided projecting from the opening side of the insertion groove, arranged opposite each other with respect to the pressure-contact blade while the pressure-contact blade is inserted in the insertion groove, and configured to bring the part of the electric wire into pressure contact with the pressure-contact blade by pressing the electric wire; and the recess provided between the protrusions, and configured to form the bent section in the electric wire when pressed by the protrusions. For this reason, the bent section in the electric wire can be formed at a pressure-contact position of the electric wire with the pressure-contact blade.

In the electric wire pressure-contact structure according to this aspect, the length between the apexes of the protrusions and the bottom of the recess is set longer than the gap in the lock section in the locking direction. For this reason, the length of the bent section in the electric wire can be formed longer than the gap in the lock section in the locking direction.

Accordingly, even when application of tensile force to the electric wire moves the electric wire holder in a detachment direction of the electric wire holder from the housing, the movement of the electric wire due to the movement of the electric wire holder can be absorbed by the bent section which is formed at the pressure-contact position. Consequently, the displacement of the pressure-contact position of the electric wire with respect to the pressure-contact blade can be inhibited to a large extent.

The electric wire pressure-contact structure according to this aspect can inhibit the displacement of the pressure-contact position of the electric wire with respect to the pressure-contact blade using the bent section which is formed in the electric wire by the protrusions and the recess, and accordingly can enhance the reliability of the connection between the electric wire and the bus bar.

According to a second aspect of the present invention, the protrusions and the recess are provided symmetrically with respect to the insertion groove.

In the electric wire pressure-contact structure according to this aspect, the protrusions and the recess are provided symmetrically with respect to the insertion groove. For this reason, even when the tensile force is applied to either of the two end sides of the electric wire drawn out of the housing, the movement of the electric wire from the pressure-contact position due to the movement of the electric wire holder can be absorbed evenly.

The present invention can provide the electric wire pressure-contact structure which is capable of enhancing the reliability of the connection between the electric wire and the bus bar.

### BRIEF DESCRIPTION OF THE DRAWINGS

FIG. 1A is an exploded perspective view of an electric wire pressure-contact structure of an embodiment of the present invention.

FIG. 1B is a perspective view of the electric wire pressure-contact structure of the embodiment of the present invention.

FIG. 2A is a side view of the electric wire pressure-contact structure of the embodiment of the present invention.

FIG. 2B is a cross-sectional view taken along the Y-Y line of FIG. 2A.

FIG. 3A is a top view of the electric wire pressure-contact structure of the embodiment of the present invention.

FIG. 3B is a cross-sectional view taken along the X-X line of FIG. 3A.

FIG. 4A is a perspective view of an electric wire holder of the electric wire pressure-contact structure of the embodiment of the present invention.

FIG. 4B is a perspective view of the electric wire holder of the electric wire pressure-contact structure of the embodiment of the present invention, which is viewed from a rear side.

FIG. 4C is a perspective view of the electric wire holder of the electric wire pressure-contact structure of the embodiment of the present invention and electric wires.

FIG. 5A is a front view of the electric wire holder of the electric wire pressure-contact structure of the embodiment of the present invention.

FIG. 5B is a side view of the electric wire holder of the electric wire pressure-contact structure of the embodiment of the present invention.

FIG. 5C is a cross-sectional view taken along the Z-Z line of FIG. 5B.

FIG. 6 is a perspective view of an outer housing and a lens of the electric wire pressure-contact structure of the embodiment of the present invention.

FIG. 7 is a perspective view of bus bars of the electric wire pressure-contact structure of the embodiment of the present invention.

FIG. 8 is a perspective view of the bus bars and an inner housing of the electric wire pressure-contact structure of the embodiment of the present invention, as well as electronic parts.

FIG. 9 is a perspective view of an LED unit of the electric wire pressure-contact structure of the embodiment of the present invention.

FIG. 10 is a perspective view of how electric wires are retained by the electric wire holder of the electric wire pressure-contact structure of the embodiment of the present invention.

FIG. 11A is a cross-sectional view taken along the Y-Y line of FIG. 2A before the electric wire holder is fitted into the housing in the electric wire pressure-contact structure of the embodiment of the present invention.

FIG. 11B is a cross-sectional view taken along the X-X line of FIG. 3A before the electric wire holder is fitted into the housing in the electric wire pressure-contact structure of the embodiment of the present invention.

FIG. 12A is a cross-sectional view taken along the Y-Y line of FIG. 2A when pressure contact starts with fitting the electric wire holder into the housing in the electric wire pressure-contact structure of the embodiment of the present invention.

FIG. 12B is a cross-sectional view taken along the X-X line of FIG. 3A when the pressure contact starts with fitting the electric wire holder into the housing in the electric wire pressure-contact structure of the embodiment of the present invention.

FIG. 13A is a cross-sectional view taken along the Y-Y line of FIG. 2A when the pressure contact is completed with the electric wire holder fitted in the housing in the electric wire pressure-contact structure of the embodiment of the present invention.

FIG. 13B is a cross-sectional view taken along the X-X line of FIG. 3A when the pressure contact is completed with the electric wire holder fitted in the housing in the electric wire pressure-contact structure of the embodiment of the present invention.

FIG. 14A is a cross-sectional view taken along the Y-Y line of FIG. 2A when tensile force is applied to one of the electric wires in a state shown in FIG. 13A.

FIG. 14B is a cross-sectional view taken along the X-X line of FIG. 3A when the tensile force is applied to one of the electric wires in a state shown in FIG. 13B.

### DESCRIPTION OF THE EMBODIMENTS

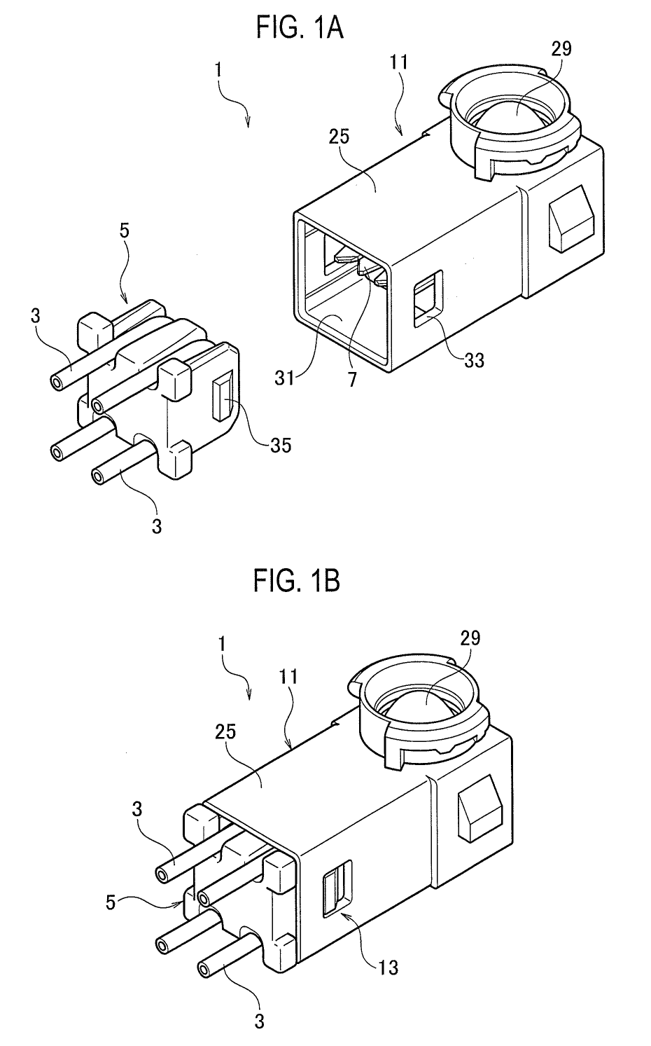

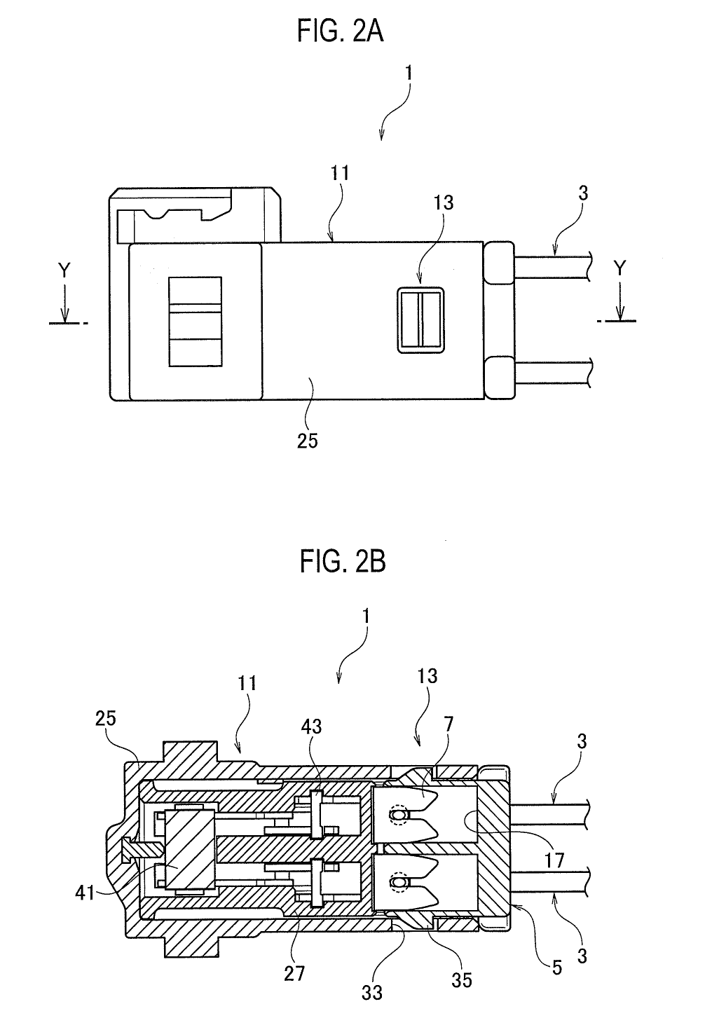

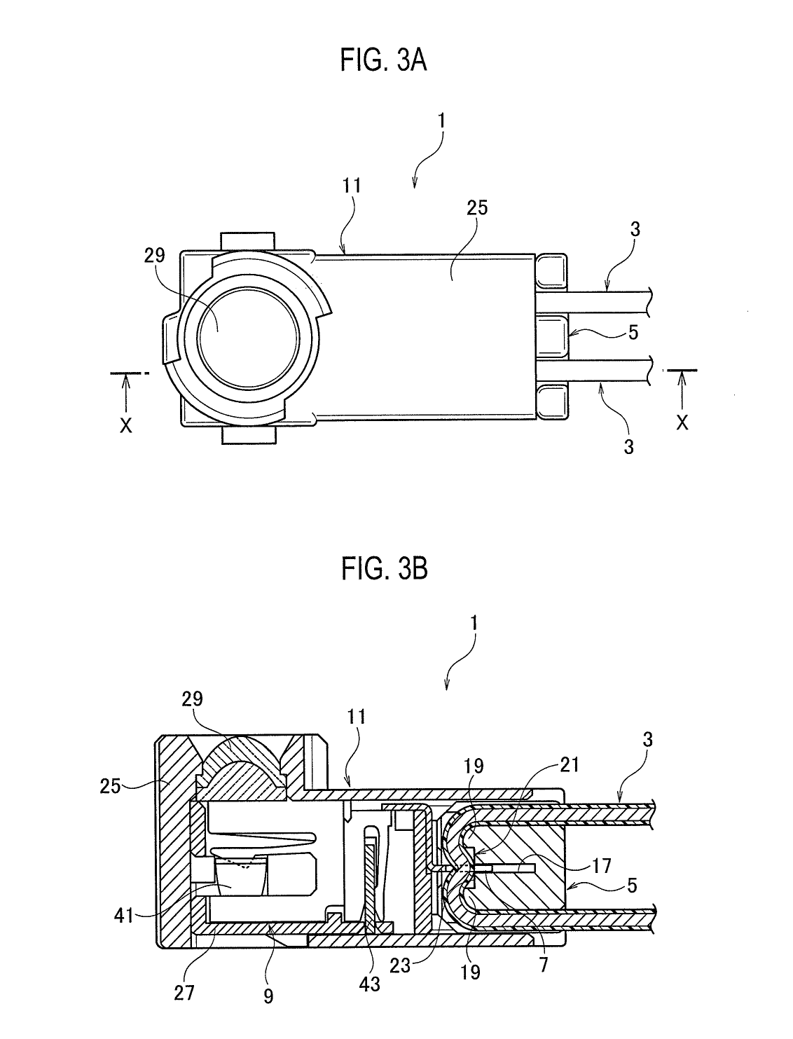

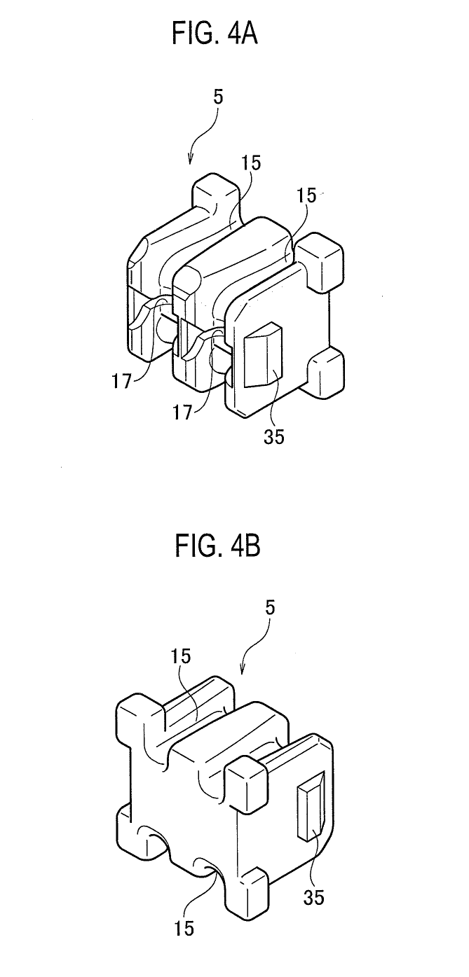

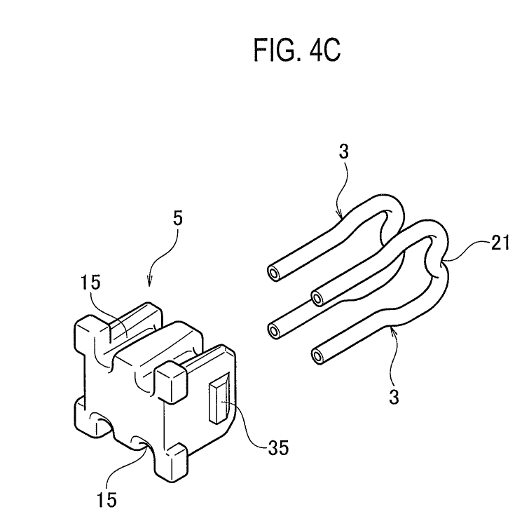

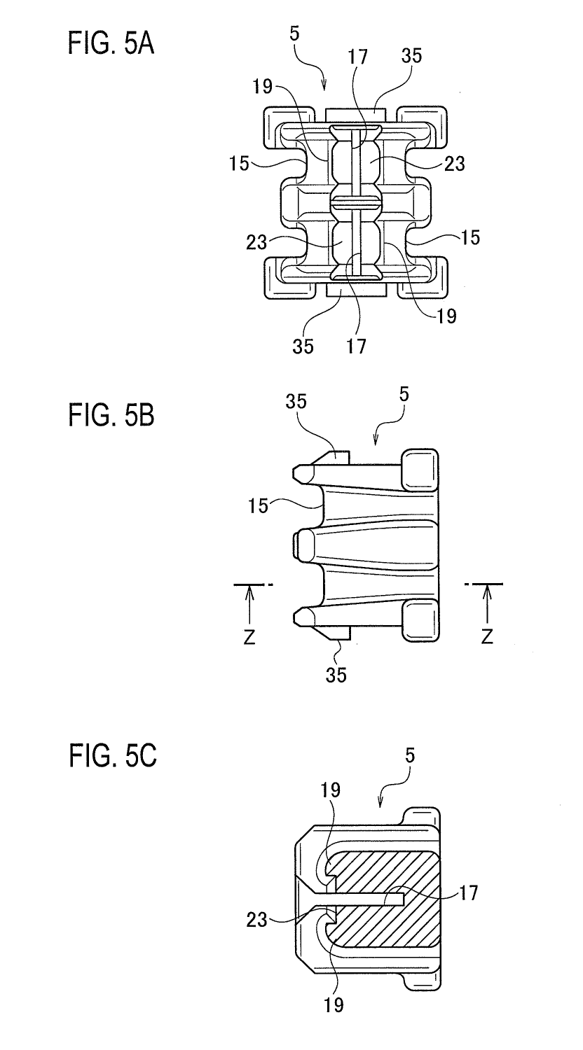

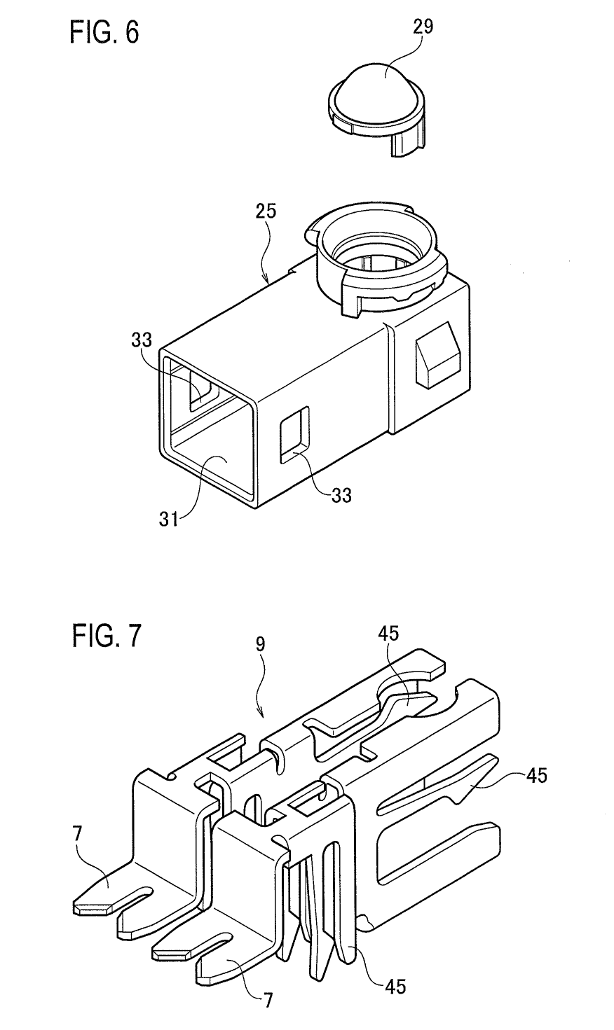

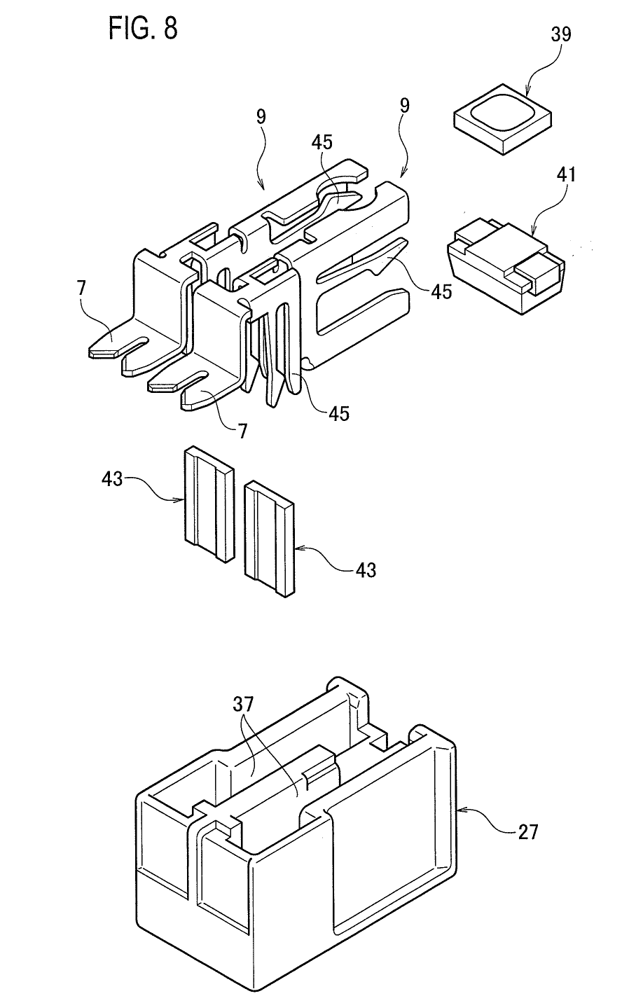

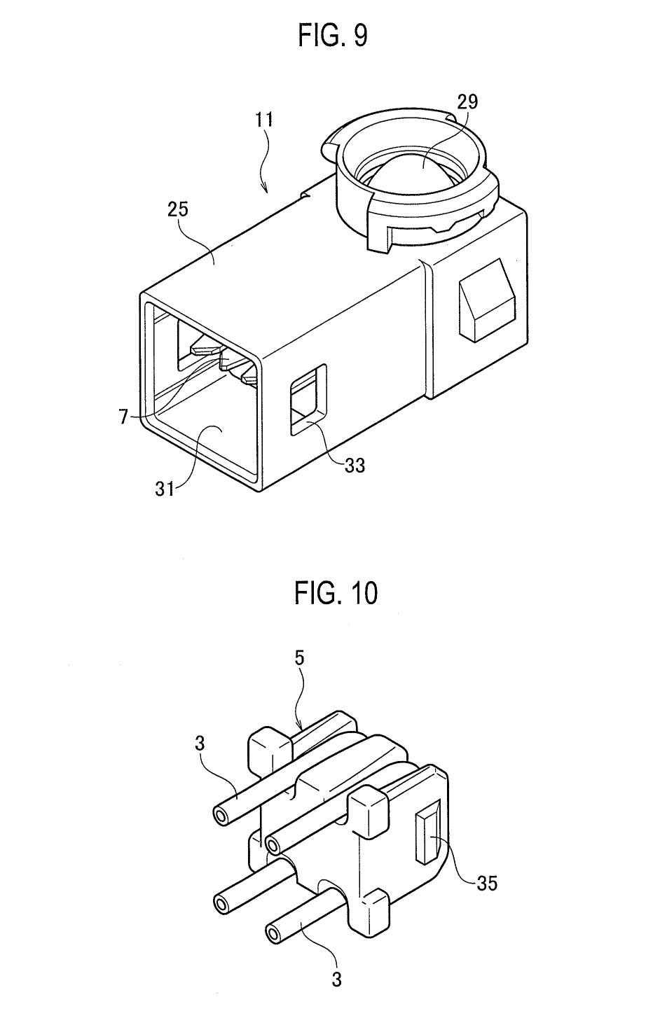

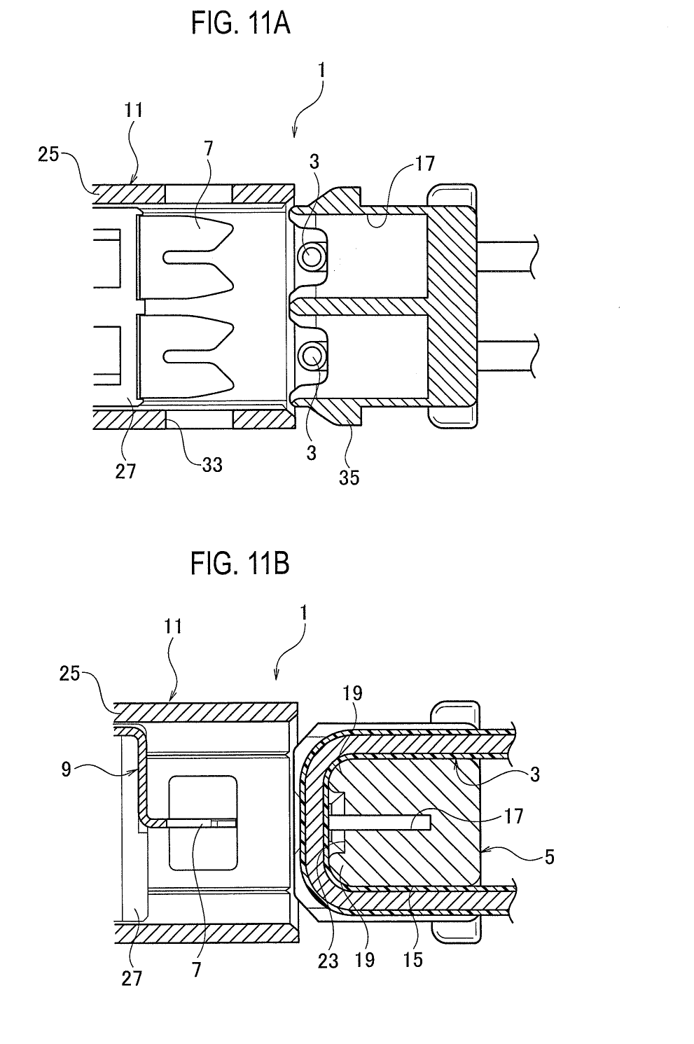

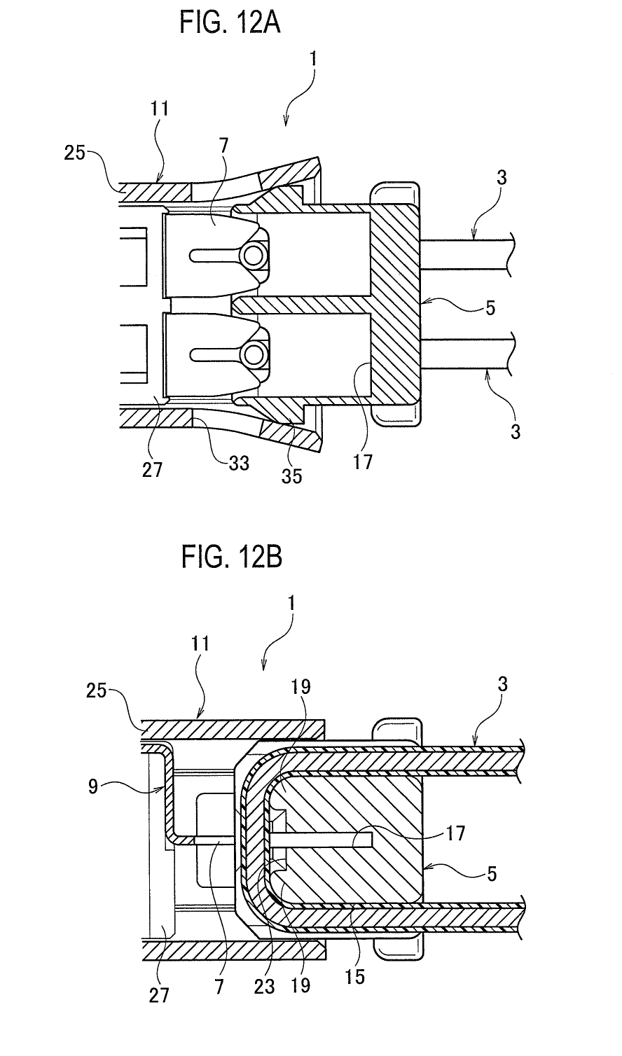

Referring to FIGS. 1A to 14B, descriptions will be provided for an electric wire pressure-contact structure of an embodiment of the present invention.

An electric wire pressure-contact structure 1 of the embodiment includes: an electric wire holder 5 configured to retain electric wires 3, 3; and a housing 11 in which bus bars 9, 9 are housed, the bus bars 9, 9 having pressure-contact blades 7, 7 for pressure contacting the electric wires 3, 3. When the electric wire holder 5 is inserted and fitted into the housing 11, the electric wire 3, 3 are brought into pressure contact with the pressure-contact blades 7, 7. The two end sides of each of the electric wires 3, 3 are drawn out of the housing 11 in a direction opposite to a direction of the insertion.

The electric wire pressure-contact structure 1 includes lock sections 13, 13 formed from: locked parts 35, 35 provided to the electric wire holder 5; and locking parts 33, 33 provided to the housing 11. In the lock sections 13, 13, the locked parts 35, 35 of the electric wire holder 5 are loosely fitted in the locking parts 33, 33 of the housing 11. Thereby, the lock sections 13, 13 make the housing 11 hold the electric wire holder 5. Descriptions will be provided for the configuration of each locked part 35 and each locking part 33.

The electric wire holder 5 includes retaining grooves 15, 15 configured to retain the electric wires 3, 3, respectively. Each retaining groove 15 includes an insertion groove 17, protrusions 19, 19 and a recess 23. The insertion groove 17 is provided to a bottom side of the retaining groove 15. A pressure-contact blade 7 is inserted in the insertion groove 17. The protrusions 19, 19 are provided projecting from an opening side of the insertion groove 17, and are arranged opposite each other with respect to the insertion groove 17. The protrusions 19, 19 bring the electric wire 3 into pressure contact with the pressure-contact blade 7 by pressing the electric wire 3. The recess 23 is provided between the protrusions 19, 19. The pressing of the protrusions 19, 19 against the electric wire 3 makes a bent section 21 in the electric wire 3.

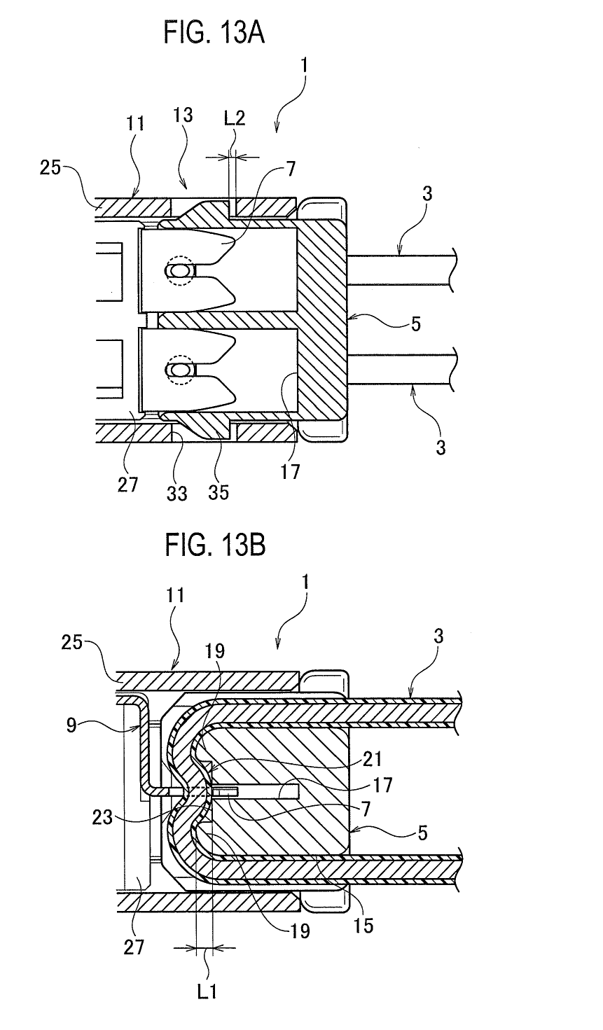

In each retaining groove 15, a length L1 (FIG. 13B) between the apexes of the protrusions 19, 19 and the bottom of the recess 23 is set to be longer than a gap L2 (FIG. 13A) between the locked part 35 and the locking part 33 in each lock section 13, where the gap L2 is formed when the locked parts 35, 35 are loosely fitted in the locking parts 33, 33, and is on the side where the electric wire holder 5 is detachable from the housing 11.

The protrusions 19, 19 and the recess 23 are provided symmetrical with respect to the insertion groove 17.

As shown in FIGS. 1A to 14B, the electric wire holder 5 is shaped like a housing. The retaining grooves 15, 15 each shaped almost like the letter U are provided to the outer peripheral surface of the electric wire holder 5. It should be noted that the number of retaining grooves may be greater than 2. The electric wires 3, 3 each obtained by covering a conductor with an insulating cover are arranged in the retaining groove 15, 15 in a way that the electric wires 3, 3 are each shaped almost like the letter U, and the two end sides of each of the electric wires 3, 3 are drawn out of the corresponding one of the retaining grooves 15, 15. Terminals, for example, are connected to the two ends of each of the electric wires 3, 3. The electric wires 3, 3 are electrically connected to a power supply, an electric appliance or the like via their respective connectors.

The insertion grooves 17, 17 in which the pressure-contact blades 7, 7 provided to the bus bars 9, 9 are inserted are provided to the bottom sides of the retaining grooves 15, 15 of the electric wire holder 5. Once the electric wire holder 5 is fitted into the housing 11, the pressure-contact blades 7, 7 are inserted into the insertion grooves 17, 17. The pressure-contact blades 7, 7 inserted in the insertion grooves 17, 17 strip parts of the insulating covers off the electric wires 3, 3, respectively. Thereby, the pressure-contact blades 7, 7 come into contact with the conductors of the electric wires 3, 3, and the electric wires 3, 3 accordingly establishes electrical conduction with the bus bars 9, 9.

The housing 11 includes an outer housing 25 and an inner housing 27. The outer housing 25 is shaped like a housing. A lens 29 is mounted on the upper surface of the outer housing 25. An opening 31 is provided to one side surface of the outer housing 25. After the inner housing 27 is housed in the outer housing 25, the electric wire holder 5 is housed in the outer housing 25 in a way that the electric wire holder 5 closes the opening 31 of the outer housing 25.

The outer housing 25 is provided with the locking parts 33, 33 for the lock sections 13, 13. The electric wire holder 5 is provided with the locked parts 35, 35 for the lock sections 13, 13. The locking parts 33, 33 are formed from hole portions which are provided to the two side surfaces of the outer housing 25. The locked parts 35, 35 are formed from protrusions which are provided to the two side surfaces of the electric wire holder 5, and which respectively have inclination surfaces which incline in the insertion direction.

Once the electric wire holder 5 is inserted into the outer housing 25 from the opening 31 of the outer housing 25, the locked parts 35, 35 are placed inside the locking parts 33, 33, and the locked parts 35, 35 are loosely fitted in the locking parts 33, 33. This prevents the electric wire holder 5 from being detached from the outer housing 25, and the inner housing 27 housed in the outer housing 25 from being detached from the outer housing 25.

The inner housing 27 is shaped like a housing, and is housed in the outer housing 25 from the opening 31 of the outer housing 25. Housing chambers 37, 37 in which the bus bars 9, 9 are housed are provided to the inside of the inner housing 27.

Each bus bar 9 is formed by applying a blanking process and a folding process to an electrical-conductive thin material. The bus bars 9, 9 are formed bilaterally symmetrical, and are arranged in parallel to each other. The bus bars 9, 9 include: electronic part connecting portions 45, 45 to which resistors 43, 43 are electrically connected, and which are formed from elastic contact pieces; and the two-pronged pressure-contact blades 7, 7 electrically connected to the electric wires 3, 3 retained by the electric wire holder 5 by pressure contact.

The bus bars 9, 9 are housed in the housing chambers 37, 37 of the inner housing 27 in a state where an LED chip 39 serving as a power supply, a Zener diode 41 configured to protect the LED chip 39, and the resistors 43, 43 are connected to the electronic part connecting portions 45, 45. In addition, the inner housing 27 is housed in the outer housing 25 in a way that the pressure-contact blades 7, 7 of the bus bars 9, 9 are located on the side of the opening 31 of the outer housing 25.

It should be noted that in a case where the inner housing 27 has openings at positions corresponding to the electronic part connecting portions 45, 45 of the bus bars 9, 9, the above-mentioned electronic parts may be connected to the electronic part connecting portions 45, 45 of the bus bars 9, 9 from the openings of the inner housing 27 after only the bus bars 9, 9 are housed in the housing chambers 37, 37.

Once the inner housing 27 is housed in the outer housing 25, an LED unit is made up. While keeping this state, the electric wire holder 5 is housed in the outer housing 25 from the opening 31 of the outer housing 25. Once the electric wire holder 5 is fitted into the LED unit, the electric wires 3, 3 are brought into pressure contact with the pressure-contact blades 7, 7, and the two end sides of each of the electric wires 3, 3 are drawn out of the outer housing 25 in the direction opposite to the insertion direction, that is to say, from the opening 31.

The bringing of the electric wires 3, 3 into pressure contact with the pressure-contact blades 7, 7 by fitting the electric wire holder 5 into the housing 11 is achieved using the protrusions 19, 19 and the recess 23 which are provided to each retaining groove 15 of the electric wire holder 5.

In each retaining groove 15, the protrusions 19, 19 are provided projecting from the opening side of the insertion groove 17 which is provided to the bottom of the retaining groove 15. In each retaining groove 15, the protrusions 19, 19 are arranged such that while the pressure-contact blade 7 is inserted in the insertion groove 17, the protrusions 19, 19 are symmetrically opposite each other with respect to the pressure-contact blade 7.

Once the electric wire holder 5 is fitted into the housing 11, the protrusions 19, 19 in each retaining groove 15 respectively press two sides of the electric wire 3 which flank the pressure-contact blade 7, and bring a portion of the electric wire 3, which is situated between the protrusions 19, 19, into pressure contact with the pressure-contact blade 7. The recess 23 is provided on the side of the base ends of the protrusions 19, 19.

In each retaining groove 15, the recess 23 is provided in the opening edge portion of the insertion groove 17. To put it concretely, between the protrusions 19, 19, the recess 23 is provided symmetrically with respect to the insertion groove 17. Using pressure-contact load which is applied to the electric wire 3 when the protrusions 19, 19 bring the electric wire 3 into pressure contact with the recess 23, the recess 23 forms the bent section 21 in the electric wire 3 in a way the electric wire 3 becomes shaped like the letter M. The recess 23 houses the bent section 21 while the electric wire holder 5 is fitted in the housing 11.

In each retaining groove 15, the length L1 (FIG. 13B) between the apexes of the protrusions 19, 19 and the bottom of the recess 23 is set to be longer than the gap L2 (FIG. 13A) between the locked part 35 and the locking part 33 in each lock section 13, where the gap L2 is formed when the locked parts 35, 35 are loosely fitted in the locking parts 33, 33, and is on the side where the electric wire holder 5 is detachable from the housing 11. For this reason, the length of the bent section 21 of the electric wire 3 which is housed in the recess 23 is longer than the gap L2 in the lock section 13 in the locking direction.

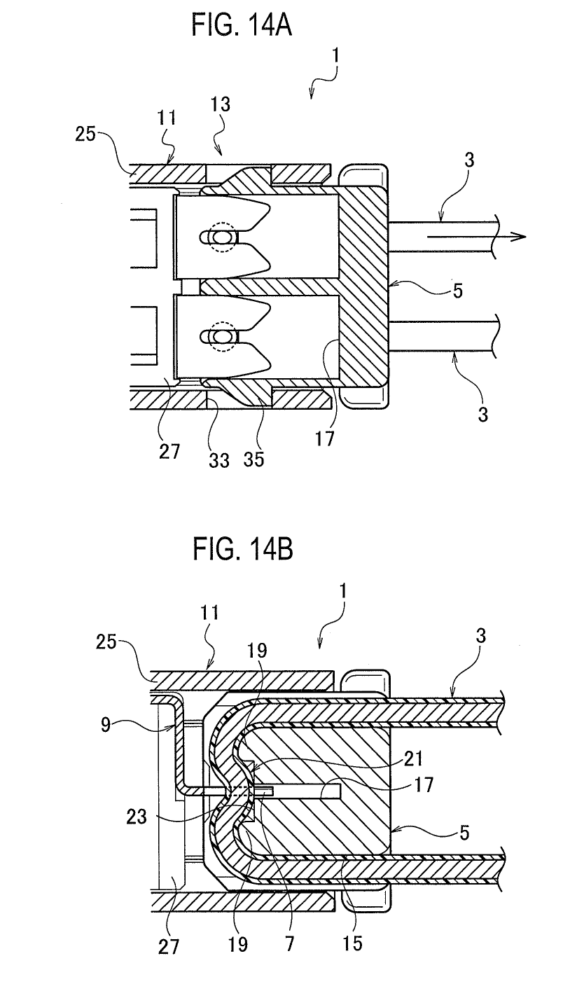

Thereby, even when application of tensile force, as indicated with an arrow in FIG. 14A, to the electric wires 3, 3 drawn out of the housing 11 moves the electric wire holder 5 by the gap L2 in the lock section 13 in the locking direction in the detachment direction of the electric wire holder 5 from the housing 11, the movement of the electric wire holder 5 can be absorbed by the bent section 21 which is longer than the gap L2. Accordingly, the pressure-contact positions of the electric wires 3, 3 with respect to the pressure-contact blades 7, 7 can be confined to slight position displacement.

A method of bringing the electric wires 3, 3 into pressure contact with the pressure-contact blades 7, 7 in the electric wire pressure-contact structure 1 is as follows. To begin with, the lens 29 is mounted on the outer housing 25, and the bus bars 9, 9 to which the electronic parts are attached are housed in the housing chambers 37, 37 in the inner housing 27.

Subsequently, the inner housing 27 is housed in the outer housing 25 by inserting the inner housing 27 into the outer housing 25 from the opening 31 of the outer housing 25. Thereby, the LED unit is made up. Thereafter, the electric wire holder 5 retaining the electric wires 3, 3 is inserted into the LED unit from the opening 31 of the outer housing 25. The insertion of the electric wire holder 5 brings the electric wires 3, 3 into contact with electric wire introduction portions which are tip ends of the pressure-contact blades 7, 7. Thereby, the pressure contact starts.

Afterward, once the electric wire holder 5 is more deeply inserted into the outer housing 25, the locked parts 35, 35 of the electric wire holder 5 become loosely fitted in the locking parts 33, 33 of the outer housing 25. For this reason, even when the tensile force is applied to the electric wires 3, 3, the locked parts 35, 35 are locked to the side surfaces of the locking parts 33, 33 on the side where the electric wire holder 5 is detachable from the outer housing 25. Thus, the electric wire holder 5 is prevented from being detached from the outer housing 25, and is stably held in the outer housing 25.

In this process, in each retaining groove 15, the recess 23 forms the bent section 21 in the electric wire 3 in the way that the electric wire 3 becomes shaped like the letter M, while the electric wire 3 is being pressed and brought by the protrusions 19, 19 of the electric wire holder 5 into pressure contact with the pressure-contact blade 7 inserted in the insertion groove 17. Thereby, the pressure contact of the electric wire 3 with the pressure-contact blade 7 is completed.

In the electric wire pressure-contact structure 1, each retaining groove 15 in the electric wire holder 5 includes: the protrusions 19, 19 provided projecting from the opening side of the insertion groove 17, arranged opposite each other with respect to the pressure-contact blade 7, and configured to bring the electric wire 3 into pressure contact with the pressure-contact blade 7 by pressing the electric wire 3; and the recess 23 provided between the protrusions 19, 19, and configured to form the bent section 21 in the electric wire 3 in conjunction with the protrusions 19, 19 pressing the electric wire 3. Thereby, the bent sections 21, 21 can be formed in the electric wires 3, 3 at the pressure-contact positions where the electric wires 3, 3 are in pressure contact with the pressure-contact blades 7, 7.

The length L1 between the apexes of the protrusions 19, 19 and the bottom of the recess 23 is set to be longer than the gap L2 in the lock section 13 in the locking direction, where the gap L2 is formed when the locked parts 35, 35 are loosely fitted in the locking parts 33, 33. For this reason, the length of the bent section 21 of the electric wire 3 can be formed longer than the gap L2 in the lock section 13 in the locking direction.

For this reason, even when the application of the tensile force to the electric wires 3, 3 moves the electric wire holder 5 in the detachment direction of the electric wire holder 5 from the housing 11, the movement of the electric wires 3, 3 due to the movement of the electric wire holder 5 can be absorbed by the bent sections 21, 21 which are formed at the pressure-contact positions of the electric wires 3, 3. Consequently, the displacement of the pressure-contact positions of the electric wires 3, 3 with respect to the pressure-contact blades 7, 7 can be inhibited to a large extent.

The electric wire pressure-contact structure 1 can inhibit the displacement of the pressure-contact positions of the electric wires 3, 3 with respect to the pressure-contact blades 7, 7 using the bent section 21 of the electric wire 3 which is formed in each retaining groove 15 by the protrusions 19, 19 and the recess 23, as well as accordingly can enhance the reliability of the connection between the electric wires 3, 3 and the bus bars 9, 9.

In each retaining groove 15, the protrusions 19, 19 and the recess 23 are provided symmetrically with respect to the insertion groove 17. For this reason, even when the tensile force is applied to either of the two end sides of each electric wire 3 drawn out of the housing 11, the movement of the electric wire 3 from the pressure-contact position due to the movement of the electric wire holder 5 can be absorbed evenly.

Although the two electric wires are retained by the electric wire holder in the electric wire pressure-contact structure of the embodiment of the present invention, the electric wire pressure-contact structure is not limited to this case. One electric wire, or three or more electric wires may be retained by the electric wire holder. In this case, the bus bars may be provided with as many pressure-contact blades as the electric wires.

In addition, although in the electric wire pressure-contact structure of the embodiment of the present invention, the housing 11 is provided with the locking parts 33, 33 for the lock sections 13, 13 and the electric wire holder 5 is provided with the locked parts 35, 35 for the lock sections 13, 13, the electric wire pressure-contact structure is not limited to this case. Instead, however, the locking parts 33, 33 and the locked parts 35, 35 for the lock sections 13, 13 may be provided such that: the housing 11 is provided with the locked parts 35, 35; and the electric wire holder 5 is provided with the locking parts 33, 33.

What is claimed is:

1. An electric wire pressure-contact structure comprising:
an electric wire holder configured to retain an electric wire; and
a housing in which a bus bar is housed, the bus bar having a pressure-contact blade for pressure contacting the electric wire, wherein
when the electric wire holder is inserted and fitted into the housing, the electric wire is brought into pressure contact with the pressure-contact blade, and two end sides of the electric wire are drawn out of the housing in a direction opposite to a direction of the insertion,
a locking part is provided to one of the electric wire holder and the housing,
a locked part is provided to the other of the electric wire holder and the housing,
a lock section includes the locking part and the locked part,
the lock section makes the housing hold the electric wire holder by loosely fitting the locked part into the locking part,
the electric wire holder includes
a retaining groove configured to retain the electric wire,
an insertion groove which is provided on a bottom side of the retaining groove, and into which the pressure-contact blade is to be inserted,
a pair of protrusions provided projecting from an opening side of the insertion groove, and arranged opposite each other with respect to the pressure-contact blade while the pressure-contact blade is inserted in the insertion groove, the protrusions configured to bring part of the electric wire into pressure contact with the pressure-contact blade by pressing the electric wire, and
a recess provided between the protrusions, and configured to forma bent section in the electric wire when the electric wire is pressed by the protrusions, and
a length between apexes of the protrusions and a bottom of the recess is set to be longer than a gap between the locked part and the locking part, the gap being formed when the locked part is loosely fitted in the locking part in the lock section and being on a side where the electric wire holder is detachable from the housing.

2. The electric wire pressure-contact structure according to claim 1, wherein the protrusions and the recess are provided symmetrically with respect to the insertion groove.
